(19) United States
(12) Patent Application Publication
(10) Pub. No.: US 2014/0009178 A1
(43) Pub. Date: Jan. 9, 2014

(54) IMPEDANCE MEASURING DEVICE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: YUN BAI, Shenzhen (CN); JI-CHAO LI, Shenzhen (CN); SONG-LIN TONG, Shenzhen (CN)

(73) Assignee: HON HAI PRECISION INDUSTRY CO., LTD., New Taipei (TW)

(21) Appl. No.: 13/924,645

(22) Filed: Jun. 24, 2013

(30) Foreign Application Priority Data
Jul. 6, 2012 (CN) 2012102334099

(51) Int. Cl. G01R 27/02

(52) U.S. Cl. CPC G01R 27/02
USPC 324/713

(57) ABSTRACT

An impedance measuring device for an electronic component includes a constant voltage source, a load supplying circuit, a voltage detection circuit, and a controller. The constant voltage source outputs an input voltage. The load supplying circuit supplies a load resistor that is electronically connected in series with the electronic component between the constant voltage source and ground. The voltage detection circuit detects a voltage across the load resistor. The controller receives the voltage across the load resistor from the voltage detection circuit, and calculates an equivalent impedance of the electronic component according to the input voltage, the voltage across the load resistor, and the resistance of the load resistor.

### BACKGROUND

1. Technical Field

The exemplary disclosure generally relates to measuring devices, and particularly to an impedance measuring device.

2. Description of Related Art

An impedance of an electronic component, such as a voltage regulator module (VRM), is usually defined with a certain value, so that designers can pre-design an output capability of a similar impedance value, thereby matching impedances, reducing reflected waves, and reducing noise. In use, if the impedance of the electronic component is out of a normal range, a circuit connected to the output of the electronic component will mismatch. Therefore, there is a need to measure the impedance of the electronic component.

Therefore, there is room for improvement within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the disclosure.

FIG. 1 shows a block diagram of an exemplary embodiment of an impedance measuring device.

FIG. 2 shows a simplified model diagram of a load of the impedance measuring device shown in FIG. 1 and an electronic component measured by the impedance measuring device shown in FIG. 1.

FIG. 3 shows a circuit diagram of a controller, a constant voltage source, a switch circuit, and an alarm control circuit of the impedance measuring device shown in FIG. 1.

FIG. 4 shows a load supplying circuit and a current detection circuit of the impedance measuring device shown in FIG. 1.

FIG. 5 shows a voltage detection circuit of the impedance measuring device shown in FIG. 1.

### DETAILED DESCRIPTION

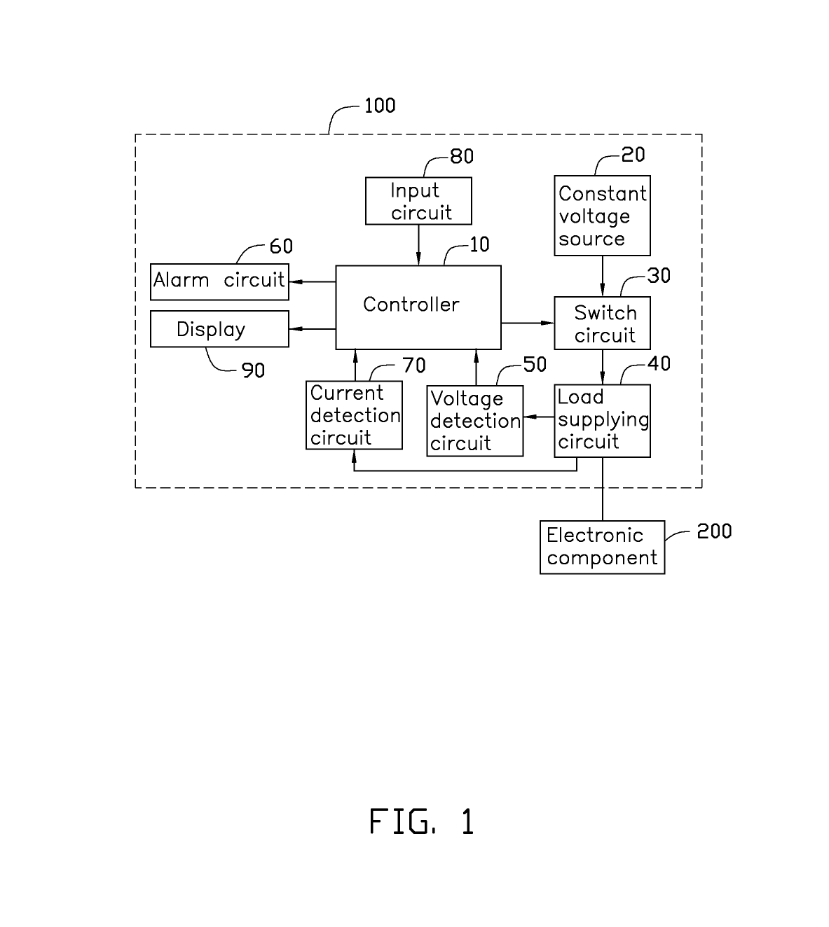

FIG. 1 shows a block diagram of an exemplary embodiment of an impedance measuring device 100 for an electronic component 200, such as a voltage regulator module (VRM). The impedance measuring device 100 includes a controller 10, a constant voltage source 20, a switch circuit 30, a load supplying circuit 40, a voltage detection circuit 50, an alarm circuit 60, a current detection circuit 70, an input circuit 80, and a display 90.

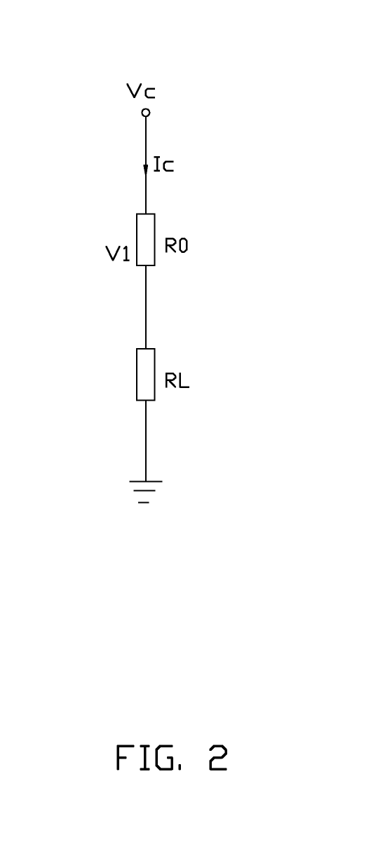

FIG. 2 shows a simplified model diagram of a load of the impedance measuring device 100 shown in FIG. 1 and an electronic component measured by the impedance measuring device 100 shown in FIG. 1. The load supplying circuit 40 includes a load resistor R0. An equivalent impedance of the electronic component 200 is set as RL. The load resistor R0 and the equivalent impedance RL are electronically connected in series between the constant voltage source 20 and ground. The constant voltage source 20 outputs an input voltage Vc to the load resistor R0 and the equivalent impedance RL. A voltage across the load resistor R0 is set as V1, a current flowing through the load resistor R0 and the equivalent impedance RL is set as Ic. Therefore, a first equation:

$$Ic = \frac{Vc}{R 0 + RL} = \frac{V 1}{R 0}$$

can be obtained; and the equivalent impedance RL can be calculated by a second equation:

$$RL = \frac{R 0 ( Vc - V 1 )}{V 1} .$$

Thus, the controller 10 can calculates the equivalent impedance RL according to the input voltage Vc, the load resistor R0, and the voltage V1 across the load resistor R0.

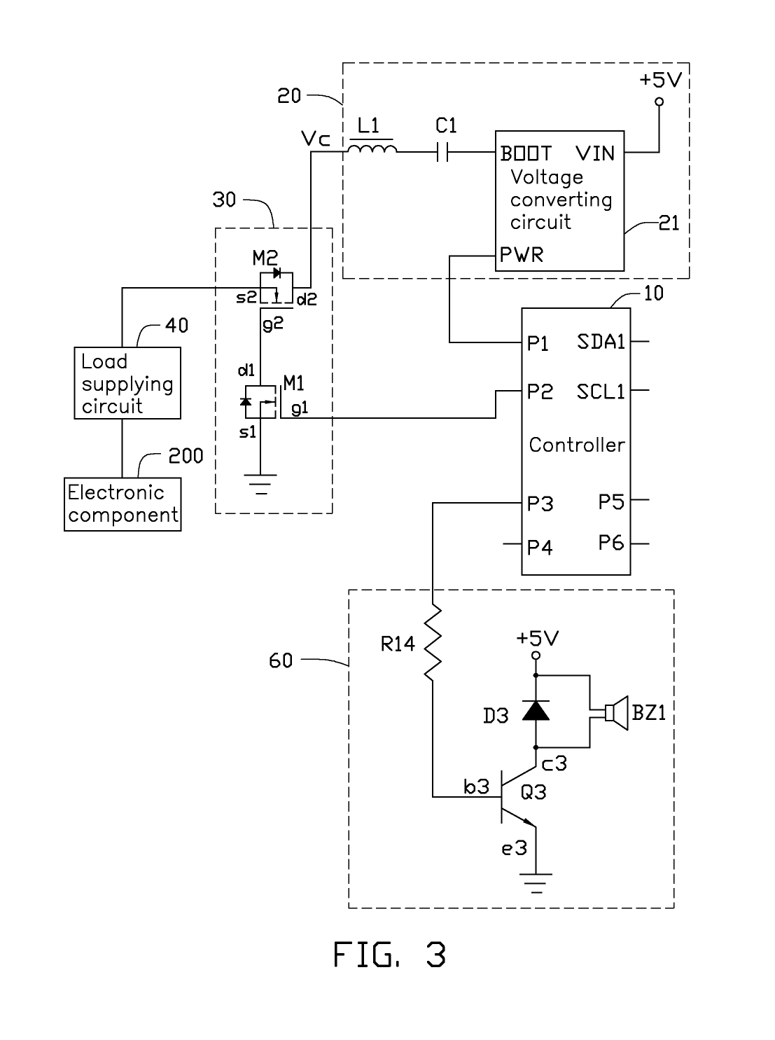

FIG. 3 shows a circuit diagram of the controller 10, the constant voltage source 20, the switch circuit 30, and the alarm control circuit 60 of the impedance measuring device 100 shown in FIG. 1. The controller 10 includes an input pin P1, a switch control pin P2, an alarm control pin P3, a voltage detection pin P4, two gate control pins P5 and P6, a data pin SDA1, and a clock pin SCL1.

The constant voltage source 20 includes a voltage converting circuit 21, a capacitor C1, an inductor L1, and a +5V power supply. The voltage converting circuit 21 converts a voltage output from the +5V power supply into the input voltage Vc, and output the input voltage Vc via the capacitor C1 and the inductor L1. In one embodiment, the input voltage Vc is 1V. The voltage converting circuit 21 includes an input pin VIN, an output pin BOOT, and a feedback pin PWR. The input pin VIN is electronically connected to the +5V power supply, the output pin BOOT is electronically connected to the inductor L1 via the capacitor C1, and the feedback pin PWR is electronically connected to the input pin P1 of the controller 10. When the voltage converting circuit 21 outputs the input voltage Vc, and the input voltage Vc is steady, the voltage input converting circuit 21 outputs a power good signal PG to the controller via the feedback pin PWR.

In the exemplary embodiment, the constant voltage source 20 is electronically connected to the load supplying circuit 40 and the electronic component 200 via the switch circuit 30. The controller 10 controls an electrical connection between the constant voltage source 20 and the load supplying circuit 40 by controlling operations of the switch circuit 30. The switch circuit 30 includes a first metal-oxide-semiconductor field-effect transistor (MOSFET) M1, and a second MOSFET M2. A gate g1 of the first MOSFET M1 is electronically connected to the switch control pin P2 of the controller 10; a source of the first MOSFET M1 is grounded; and a drain d1 of the first MOSFET M1 is electronically connected to a gate g2 of the second MOSFET M2. A drain d2 of the second MOSFET M2 is electronically connected to the inductor L1 of the constant voltage source 30, and a source s2 of the second MOSFET M2 is electronically connected to the load supplying circuit 40. When the controller 10 receives the power good signal PG from the voltage converting circuit 21, the controller 10 outputs a low level voltage signal (e.g. logic 0) to the first MOSFET M1, to switch off the first MOSFET M1 and switch on the second MOSFET M2, such that the input voltage Vc is supplied to the load supplying circuit 40 via the second MOSFET M2.

The load supplying circuit 40 supplies the load resistor R0 with a suitable resistances that is about equal to a resistance of the equivalent impedance RL, to increase a precision of the measurement of the equivalent impedance RL. When equivalent impedance RL has a resistance at a kilo-ohm level or a mega-ohm level, the resistance of the load resistor R0 is set to be at the kilo-ohm level or the mega-ohm level correspondingly. When the equivalent impedance RL has a resistance limited to ohm level (e.g., less than 1 kilo-ohm), the resistance of the load resistor R0 is set to be at the ohm level correspondingly.

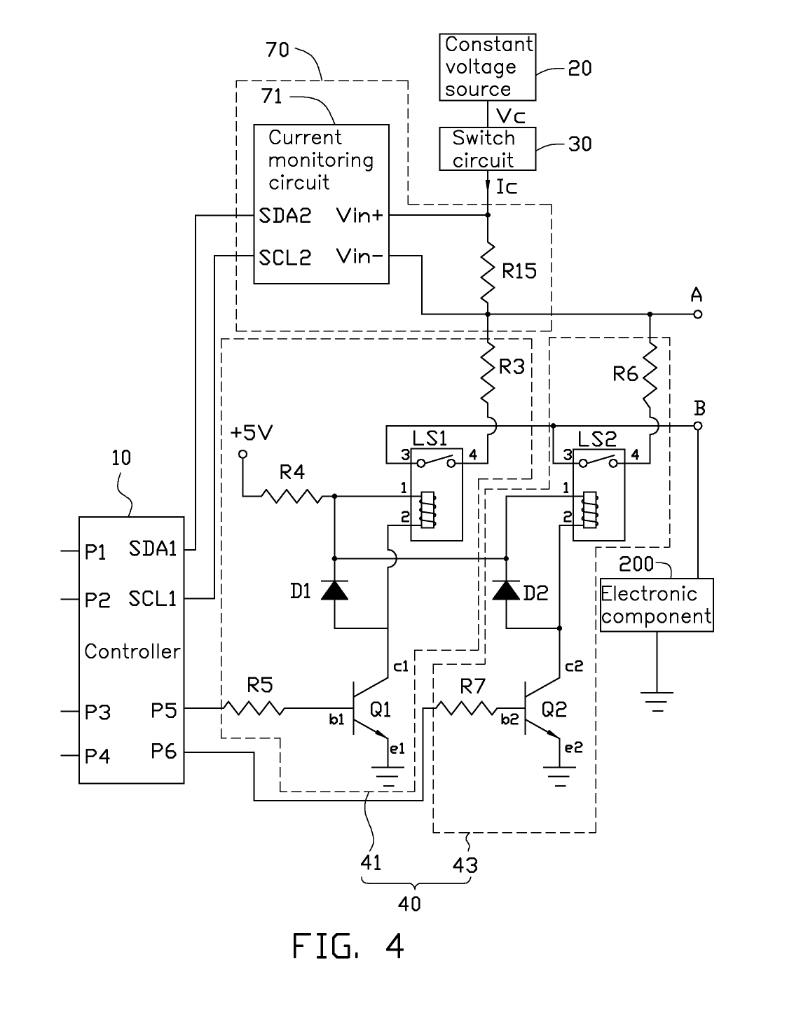

FIG. 4 shows the load supplying circuit 40 and the current detection circuit 60 of the impedance measuring device 100 shown in FIG. 1. The load supplying circuit 40 includes a plurality of gate units connected in parallel. In the exemplary embodiment, the load supplying circuit 40 includes two gate units, which are gate unit 41 and gate unit 43. The gate unit 41 includes a load resistor R3, two biasing resistors R4 and R5, a relay LS1, a bipolar junction transistor (BJT) Q1, and a discharge diode D1. The relay LS1 includes control terminals 1 and 2, and connection terminals 3 and 4. The control terminals 1 and 2 are connected by an inductor (not labeled). The control terminal 1 is electronically connected to the +5V power supply via the biasing resistor R4; the control terminal 2 is electronically connected to a collector c1 of the BJT Q1; the connection terminal 3 is grounded via the electronic component 200; and the connection terminal 4 is electronically connected to the switch circuit 30 via the load resistor R3. A base b1 of the BJT Q1 is electronically connected to the gate control pin P5 of the controller 10 via the biasing resistor R5; and an emitter e1 of the BJT Q1 is grounded. An anode of the discharge diode D1 is electronically connected to a node between the control terminal 2 and the collector c1 of the BJT Q1, and a cathode of the discharge diode D1 is electronically connected to a node between the control terminal 1 and the biasing resistor R4. The discharge diode D1 is discharge a self-induction current generated by the inductor of the relay LS1 when the relay LS1 is opened.

The gate unit 43 has approximately same components and electrical connections as the components and electrical connections of the gate unit 41, and differs from the gate unit 41 only in that: a base b2 of a BJT Q2 of the gate unit 43 is electronically connected to the gate control pin P6 of the controller 10 via a biasing resistor R7, and a load resistor R6 of the gate unit 43 has a resistance that is different from the resistance of the load resistor R3. For example, the resistance of the load resistor R3 is 10 ohms, and the resistance of the load resistor R6 is 10 kilo-ohms When a load resistor having a small resistance (such as less than 1 kilo-ohm) is desired to connected to the electronic component 200, the controller 10 outputs a high level voltage signal (e.g. logic 1) to the base b1 of the BJT Q1 via the gate control pin P5, and outputs a low level voltage signal to the base b2 of the BJT Q2 via the gate control pin P6. At this time, the BJT Q1 is switched on, the connection terminals 3 and 4 of the relay LS1 are connected, such that the load resistor R3 is electronically connected between the constant voltage source 10 and the electronic component 200, and the load resistor R3 serves as the load resistor R0 shown in FIG. 2. Alternatively, when a load resistor having a big resistance is needs to be connected to the electronic component 200, the controller 10 outputs a low level voltage signal to the base b1 of the BJT Q1 via the gate control pin P5, and outputs a high level voltage signal to the base b2 of the BJT Q2 via the gate control pin P6. At this time, the BJT Q2 is switched on, the connection terminals 3 and 4 of the relay LS2 are connected, such that the load resistor R6 is electronically connected between the constant voltage source 10 and the electronic component 200, and the load resistor R6 serves as the load resistor R0 shown in FIG. 2.

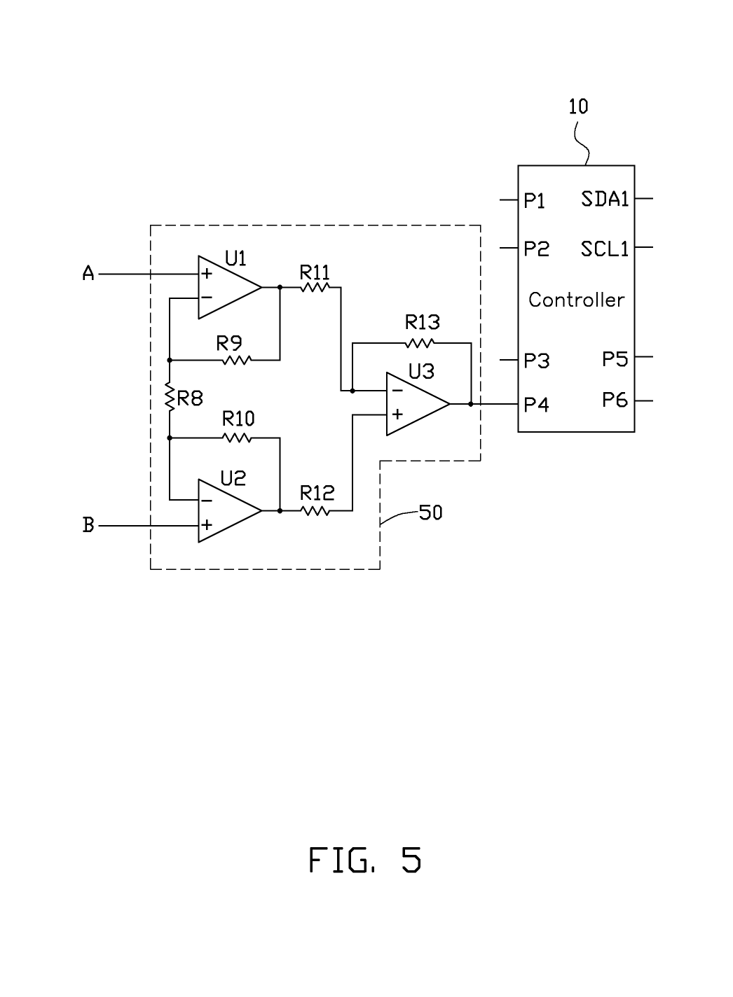

FIG. 5 shows a voltage detection circuit 50 of the impedance measuring device 100 shown in FIG. 1. The voltage detection circuit 50 detects a voltage V1 across the load resistor R0, amplifies the voltage V1, and outputs the amplified voltage V1 to the controller 10. The voltage detection circuit 50 includes a first operational amplifier U1, a second operational amplifier U2, a differential amplifier U3, and resistors R8-R13. A node between the load resistors R3 and R6 is labeled as A, a node between the connection terminal 3 of the relay LS 1 and the terminal 3 of the relay LS2 is labeled as B. A non-inverting input terminal of the first operational amplifier U1 is electronically connected to the node A, a non-inverting input terminal of the second operational amplifier U2 is electronically connected to the node B. An inverting input terminal of the first operational amplifier U1 is electronically connected to an inverting input terminal of the second operational amplifier U2 via the resistor R8. An output terminal of the first operational amplifier U1 is electronically connected to an inverting input terminal of the differential amplifier U3 via the resistor R11. An output terminal of the second operational amplifier U2 is electronically connected to a non-inverting input terminal of the differential amplifier U3 via the resistor R12. The resistor R9 is electronically connected between the output terminal and the inverting input terminal of the first operational amplifier U1, the resistor R10 is electronically connected between the output terminal and the inverting input terminal of the second operational amplifier U2, the resistor R13 is electronically connected between the output terminal and the inverting input terminal of the differential amplifier U3.

The first and second operational amplifiers U1 and U2 cooperate to form a pair of symmetrical non-inverting amplifiers, which amplify voltages on the two terminals of the load resistor R0, and transmit the amplified voltages to the inverting input terminal and the non-inverting input terminal of the differential amplifier U3. The differential amplifier U3 amplifies a difference between the voltages on the inverting and non-inverting input terminals, and then outputs the amplified voltage difference to the controller 10. The total amplification factor of the voltage detection unit can be regulated by regulating the resistance of the resistor R8. The controller 10 converts the voltage output from the differential amplifier U3 to a digital value, and calculates the voltage V1 according to the digital value and the total amplification factor, and further calculates a first value of the equivalent impedance RL according to the voltage V1 and the aforementioned second equation.

When the controller 10 detects that the voltage V1 across the load resistor R0 is equal to the input voltage Vc, the controller 10 determines the electronic component 200 is short, and activates the alarm circuit 60. The alarm circuit 60 (shown in FIG. 3) includes a BJT Q3, a buzzer BZ1, a freewheeling diode D3, and a biasing resistor R14. A base b3 of the BJT Q3 is electronically connected to the alarm control pin P3 of the controller 10 via the biasing resistor R14, an emitter e3 of the BJT Q3 is grounded, and a collector c3 of the BJT Q3 is electronically connected to the +5V power supply via the buzzer BZ1. An anode of the freewheeling diode D3 is electronically connected to a node between the buzzer BZ1 and the +5V power supply, and a cathode of the freewheeling diode D3 is electronically connected to a node between the buzzer BZ1 and the collector c3 of the BJT Q3. The freewheeling diode D3 discharges a self-induction current generated by a coil (not shown) of the buzzer BZ1. When the controller 10 determines that the electronic component 200 is shorted, the controller outputs a high voltage level signal to the base b3 of the BJT Q3 to switch on the BJT Q3, thereby activating the buzzer BZ1.

A third equation:

$$RL = \frac{Vc}{Ic} - R 0$$

can be obtained according the aforementioned first and second equations. The controller 10 can calculate a second value of the equivalent impedance RL according to the current Ic and the third equation. For increasing a precision of the measurement of the equivalent impedance RL, the controller 10 calculates an average value of the first value of the equivalent impedance RL calculated by the second equation and the second value of the equivalent impedance RL calculated by the third equation. The average value is the final measured value of the equivalent impedance RL.

Referring back to FIG. 4, the current detection circuit 70 measures the current Ic flowing through the load resistor R0 and the electronic component 200. The current detection circuit 70 includes a current detection resistor R15 and a current monitoring circuit 71. The current detection resistor R15 is electronically connected between the node A and the switch circuit 30. The current monitoring circuit 71 includes a first voltage input pin Vin+, a second voltage input pin Vin−, a data pin SDA2, and a clock pin SCL2. The data pin SDA2 of the current monitoring circuit 71 is electronically connected to the data pin SDA1 of the controller 10, and the clock pin SCL2 of the current monitoring circuit 71 is electronically connected to the clock pin SCL1 of the controller 10. The first voltage input pin Vin+ is electronically connected to one terminal of the current detection resistor R15, and the second voltage input pin Vin− is electronically connected to the other terminal of the current detection resistor R15. The current monitor circuit 71 detects a voltage across the current detection resistor R15 via the first and second voltage input pins Vin+ and Vin−, converts the voltage across the current detection resistor R15 into the current Ic according to a resistance of the current detection resistor R15, and outputs the current Ic to the controller 10 via the data pin SDA2 and the clock pin SCL2. Since the current detection resistor R15 is connected in series with the load resistor R0 and the electronic component 200, the current detection resistor R15 is less than 0.1 ohms, to decrease an influence to the measurement result of the equivalent impedance RL. In the exemplary embodiment, the value of the current detection resistor R15 is 0.02 ohms.

The input unit 80 is electronically connected to the controller 10, to control operation of the controller 10. The input unit 80 can include a plurality of keys (not shown) electronically connected to the controller 10. For example, the input unit 80 includes a power-on key, a power-off key, a measurement start key, and a measurement stop key.

The display 90 is electronically connected to the controller 10, to display the measured value of the equivalent impedance RL of the electronic component.

The working process of the impedance measuring device 100 can be carried out by, but is not limited to, the following steps. The power-on key of the input unit 80 is pressed down, the controller 10 is powered on and prepares for measurement. When the measurement start key of the input unit 80 is pressed down, since the impedance of the electronic component 200 is unknown at this time, the controller 10 controls the load supplying circuit 40 to activate any one of the gate units, the switch circuit 30 connects the constant voltage source 20 to the load resistor R0 of the load supplying circuit 40. The controller 10 controls the voltage detection circuit 50 to detect the voltage across the load resistor R0. If the voltage across the load resistor R0 is much higher than or is much lower than Vc/2, the controller 10 controls the load supplying circuit 40 to activate another one of the gate units, until the voltage across the load resistor R0 is about equal to Vc/2. The controller 10 calculates the value of the equivalent impedance RL of the electronic component 200 according to the second equation and/or the third equation, and displays the calculated value of the equivalent impedance RL on the display 90.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An impedance measuring device for an electronic component, comprising:
a constant voltage source outputting an input voltage;
a load supplying circuit comprising a load resistor that is electronically connected in series with the electronic component between the constant voltage source and ground;
a voltage detection circuit detecting a voltage across the load resistor; and
a controller electronically connected to the voltage detection circuit and the load supplying circuit, the controller receiving the voltage across the load resistor from the voltage detection circuit, and calculating an equivalent impedance of the electronic component according to the input voltage, the voltage across the load resistor, and the resistance of the load resistor.

2. The impedance measuring device of claim 1, wherein the resistance of the load resistor is about equal to the resistance of the equivalent impedance of the electronic component.

3. The impedance measuring device of claim 1, wherein the load supplying circuit comprises a plurality of gate units connected in parallel, each gate unit comprises a load resistor, the load resistors of the gate units have different resistances, the controller controls the load supplying circuit to connect the load resistor of one of the gate units in series with the electronic component.

4. The impedance measuring device of claim 3, wherein the load supplying circuits further comprises a power supply, each gate unit further comprises a relay and a bipolar junction transistor (BJT), the relay comprises two control terminals, two connection terminals, and a coil electronically connected between the two control terminals; one of the control terminals is electronically connected to the power supply, the other one of the control terminals is electronically connected to a collector of the BJT; one of the connection terminals is electronically connected to the electronic component, the other one of the connection terminals is electronically connected to the output of the constant voltage source via the load resistor; a base of the BJT is electronically connected to the controller, and an emitter of the BJT is grounded.

5. The impedance measuring device of claim 1, wherein the constant voltage source comprises an input power, a voltage converting circuit, a capacitor, and an inductor; the inductor is electronically connected to the voltage converting circuit via the capacitor; the voltage converting circuit converts a voltage output from the input power into the input voltage, and outputs the input voltage via the capacitor and the inductor.

6. The impedance measuring device of claim 1, further comprising a switch circuit electronically connected between the load supplying circuit and the constant voltage source, wherein the controller controls the operation of the switch unit to switch an electrical connection between the constant voltage source and the load supplying circuit.

7. The impedance measuring device of claim 6, wherein the switch circuit comprises a first metal-oxide-semiconductor field-effect transistor (MOSFET), and a second MOSFET, a gate of the first MOSFET is electronically connected to the controller, a source of the first MOSFET is grounded, and a drain of the first MOSFET is electronically connected to a gate of the second MOSFET; a drain of the second MOSFET is electronically connected to the output of the constant voltage source, and a source of the second MOSFET is electronically connected to the load supplying circuit.

8. The impedance measuring device of claim 1, wherein the voltage detection circuit includes a first operational amplifier, a second operational amplifier, a differential amplifier, and a first resistor; a non-inverting input terminal of the first operational amplifier is electronically connected to one terminal of the load resistor, a non-inverting input terminal of the second operational amplifier is electronically connected to the other terminal of the load resistor; inverting input terminals of the first and second operational amplifiers are connected via the first resistor; an output terminal of the first operational amplifier is electronically connected to an inverting input terminal of the differential amplifier, and an output terminal of the second operational amplifier is electronically connected to the non-inverting input terminal of the differential amplifier; an output terminal of the differential amplifier is electronically connected to the controller.

9. The impedance measuring device of claim 1, further comprising an alarm control circuit, wherein the controller activates the alarm control circuit when the voltage across the load resistor is equal to the input voltage.

10. The impedance measuring device of claim 9, wherein the alarm control circuit comprises a BJT, and a buzzer, a base of the BJT is electronically connected to the controller, an emitter of the BJT is grounded, and a collector of the BJT is electronically connected to a power supply via the buzzer.

11. The impedance measuring device of claim 10, wherein the alarm control circuit further comprises a freewheeling diode, an anode of the freewheeling diode is electronically connected to a node between the buzzer and the power supply, and a cathode of the freewheeling diode is electronically connected to a node between the buzzer and the collector of the BJT.

12. The impedance measuring device of claim 1, further comprising a current detection circuit detecting a current flowing through the load resistor and the electronic component, the controller calculates the equivalent impedance of the electronic component according to the current flowing through the load resistor, the resistance of the load resistor, and the input voltage.

13. The impedance measuring device of claim 12, wherein the current detection circuit comprises a current detection resistor and a current monitoring circuit electronically connected to the current detection resistor and the controller; the current detection resistor is electronically connected between the load resistor and the constant voltage source, the current monitoring circuit detects a voltage across the current detection resistor, converts the voltage across the current detection resistor into the current, and outputs the current to the controller.
